(19) United States
(12) Patent Application Publication
(10) Pub. No.: US 2025/0077755 A1
(43) Pub. Date: Mar. 6, 2025

(54) SEMICONDUCTOR DEVICE WITH REDACTED LOGIC

(71) Applicant: BAE SYSTEMS Information and Electronic Systems Integration Inc., Nashua, NH (US)

(72) Inventors: David D. Moser, Haymarket, VA (US); Daniel L. Stanley, Warrenton, VA (US); Jane O. Gilliam, Centreville, VA (US)

(73) Assignee: BAE SYSTEMS Information and Electronic Systems Integration Inc., Nashua, NH (US)

(21) Appl. No.: 18/456,648

(22) Filed: Aug. 28, 2023

(51) Int. Cl. G06F 30/343

(52) U.S. Cl. CPC G06F 30/343

(57) ABSTRACT

A semiconductor device includes a data port, a programmable logic block for executing a manufacturer test, and a processor operatively coupled to the data port. The processor is configured to assert, in a first modality, a configuration isolation signal to the data port. The data port is configured to be communicatively isolated from the programmable logic block while the configuration isolation signal is asserted. The processor is configured to de-assert, in a second modality, the configuration isolation signal from the data port. The data port is configured to be communicatively coupled to the programmable logic block while the configuration isolation signal is de-asserted. In some examples, the semiconductor device includes a communication interface communicatively coupled to the programmable logic block, wherein the processor is further configured to cause, in the first modality, data to be loaded into the programmable logic block from a first-in-first-out (FIFO) buffer of the communication interface.

### FIELD OF DISCLOSURE

The present disclosure relates to semiconductor devices, and more particularly, to techniques for redacting logic, including manufacturer test logic, from semiconductor components.

### BACKGROUND

Design for test (DFT), also referred to as design for testability, involves design techniques for integrated circuits and semiconductor components that provide testability features to the device. The added features make it easier to develop and apply manufacturing tests to the hardware. The manufacturing tests, which are specifically accommodated by the design of the device, are used to validate that the hardware has no manufacturing defects that could adversely affect the product's correct functioning. The tests can also be used, for example, by the customer for further validation, diagnostics, and maintenance.

JTAG (named after the Joint Test Action Group which codified it) is an industry standard for verifying designs and testing printed circuit boards after manufacture. JTAG specifies the use of a dedicated serial communications testing interface onboard the semiconductor device. The interface connects to an on-chip Test Access Port (TAP) that implements a stateful protocol to access a set of test registers that present chip logic levels and device capabilities of various parts. During operation, the JTAG interface is used to read data from, and write data to, various components of the device, facilitating system testing, diagnosis, and fault isolation. In some cases, the device can be analyzed at the machine instruction level or in terms of a high-level code, providing external views into at least portions of the internal configuration of the device with little to no prior knowledge of the design.

### BRIEF DESCRIPTION OF THE DRAWINGS

FIG. 1 is a block diagram of an example redacted logic system with a semiconductor device, in accordance with an example of the present disclosure.

FIG. 2 is a block diagram of the semiconductor device of FIG. 1, in accordance with an example of the present disclosure.

FIG. 3 is a block diagram of a portion of the semiconductor device of FIGS. 1 and 2, in accordance with an example of the present disclosure.

FIG. 4 is a block diagram representing first and second modalities of the semiconductor device of FIGS. 1, 2 and 3, in accordance with an example of the present disclosure.

FIG. 5 is a flow diagram of an example process for operating the device of FIG. 2, in accordance with an embodiment of the present disclosure.

Although the following detailed description will proceed with reference being made to illustrative embodiments, many alternatives, modifications, and variations thereof will be apparent in light of this disclosure.

### DETAILED DESCRIPTION

Techniques are described for redacting logic, including manufacturer test logic, from semiconductor components. In an example, a semiconductor device includes a data port and/or a control port, a programmable logic block for executing a manufacturer test, and a processor operatively coupled to the data/control port. The processor is configured to assert, in a first modality, a configuration isolation signal to the data/control port. The data port is configured to be communicatively isolated from the programmable logic block while the configuration isolation signal is asserted. The processor is further configured to de-assert, in a second modality, the configuration isolation signal from the data port. The data port is further configured to be communicatively coupled to the programmable logic block while the configuration isolation signal is de-asserted. In some examples, the semiconductor device includes a communication interface communicatively coupled to the programmable logic block, wherein the processor is further configured to cause, in the first modality, data to be loaded into the programmable logic block from a first-in-first-out (FIFO) buffer of the communication interface. The second modality occurs subsequent to loading the data into the programmable logic block.

In some examples, the programmable logic block is configured to be in a non-programmable state responsive to receiving a test isolation signal in the second modality. The test isolation signal causes a configuration signal, such as a field programmable gate array (FPGA) load file, to be isolated from the programmable logic block so that the programmable logic block cannot be modified. The programmable logic block is further configured to operate in a test mode responsive to a presence of a test selection signal in the second modality, and configured to operate in a non-test mode responsive to an absence of the test selection signal.

At the foundry, the logic of the semiconductor device, and in particular, the manufacturing test logic, is redacted so that the device is inoperable and otherwise inaccessible until test and/or operational logic is loaded, at a trusted facility, in a manner that prevents unauthorized access to one or more programmable logic blocks within the device. For example, the redacted logic prevents unauthorized access to, or a side-channel attack of, the semiconductor device design during and subsequent to manufacturing until the programmable logic blocks are loaded. For example, the techniques described herein can be used to enable only certain components needed to load logic into the programmable logic blocks while preventing unauthorized access, use, and/or reverse engineering of all wafers. Numerous other embodiments and variations of the device will be apparent.

### General Overview

Printed circuit boards, System-on-Chip (SoC) devices, and other types of electronic circuits can use one or more signal buses to route signals between various on-chip modules, components, and circuit blocks within a given chip or component. Such devices and circuits can include one or more field programmable gate arrays (FPGAs) that can be used to implement logical functions. The logical functions may, in some circumstances, include proprietary, confidential, or otherwise sensitive intellectual property (IP) that should be secured from unauthorized access or use. However, by nature of a typical application for such devices, the execution of on-chip commands between integral components of existing devices is relatively unsecure. For instance, a boundary scan or the manufacturing test logic executed via an input/output interface of the device can be used to retrieve or otherwise observe the status of each pin on the FPGA while the FPGA code is executing. Such a boundary scan can thus expose sensitive information to unauthorized users. As such, there is increasing concern that a system-level integrated circuit chip or chip set can be compromised by bad actors, who are intent on accessing secure information, reverse engineering circuit designs, disrupting functionality, or otherwise gaining unauthorized access to the SoC devices, either during manufacturing or when the chip components are obtained illicitly, such as through wafer overproduction.

As noted above, one such way a SoC device can be accessed is via a JTAG communication channel. JTAG is designed to assist with device, board, and system testing, diagnosis, and fault isolation. For example, JTAG is used for accessing sub-blocks of integrated circuits (IC), making it a powerful mechanism for debugging embedded systems which might not have any other debug-capable communications channel. In some designs, JTAG-based debugging is available from the first instruction after CPU reset, which provides access to all instructions that are executed by the device. On-chip debug modules can be used to evaluate the device directly at the machine instruction level or in terms of high-level language source code. In particular, JTAG allows device programmer hardware to transfer data into internal non-volatile device memory (e.g. complex programmable logic devices, or CPLDs). Some device programmers serve a double purpose for programming as well as debugging the device. In the case of FPGAs, volatile memory devices can also be programmed via the JTAG port. In addition, internal monitoring capabilities (temperature, voltage and current) may be accessible via the JTAG port. In this manner, manufacturing test solutions that utilize JTAG may be powerful and useful for validating semiconductors at the foundry. However, only a small number of commercial foundries now manufacture high-performance, mixed system ICs for multiple customers worldwide, giving rise to security and trust concerns. At any given such foundry, security vulnerabilities may be present in or subsequent to the fabrication process. For example, if a design is fabricated in a foundry that is not controlled by the customer, the foundry can potentially use the JTAG capabilities of the device for reverse engineering, circuit modification, and intellectual property (IP) theft, or distribute excess devices to third-parties. For at least these reasons, there is increasing concern that existing designs are insufficient to prevent or otherwise mitigate unauthorized uses or forensic examinations of semiconductor devices.

Possible example solutions to help mitigate against reverse engineering, circuit modification, and IP theft of semiconductor devices include logic encryption, camouflaging of gate layouts, password protection, and the use of dummy CPLD code to prevent the foundry from accessing certain aspects of the design. However, these solutions may prevent the foundry from performing manufacturing validation, in which case all produced chips are sent to the customer for in-house validation. Also, such secure safeguards can still be compromised in various ways by malicious actors without the knowledge of the customer.

To this end, and in accordance with an example of the present disclosure, a semiconductor device with redacted logic, and in particular, redacted manufacturing test logic, is provided so that the device is inoperable. The redacted logic prevents unauthorized access to, or a side-channel attack of, the semiconductor device design during and subsequent to manufacturing until the programmable logic blocks are loaded at, for instance, a trusted facility.

For example, the techniques described herein can be used to enable only certain components needed to load logic into the programmable logic blocks while preventing unauthorized access, use, and/or reverse engineering of all wafers. Some example embodiments protect the device from side channel attacks by preventing access to programmable logic block crossbar switches, isolating the manufacturing test block in a non-test mode until the programmable logic block load file is loaded, and by holding the programmable logic blocks in reset with clocks turned off so that they are inoperable. Numerous other embodiments and variations will be appreciated in light of this disclosure.

### Redacted Logic System

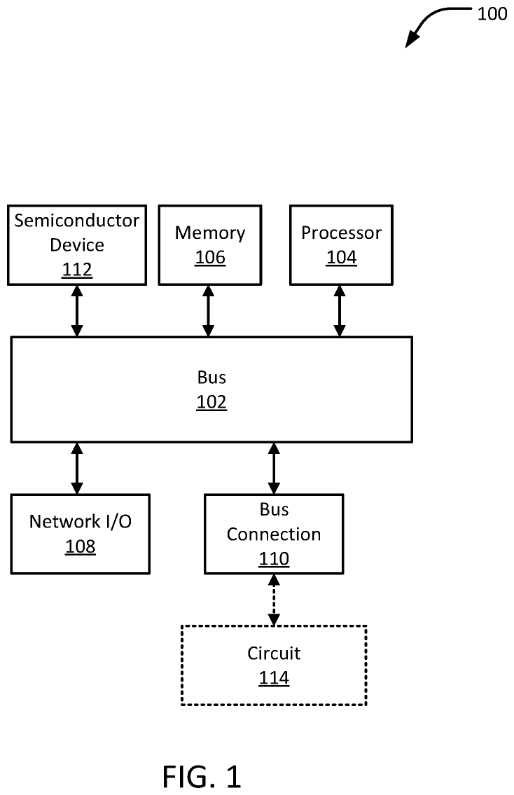

FIG. 1 is a block diagram of an example redacted logic system 100, in accordance with an example of the present disclosure. The system 100 can represent various circuit blocks, programmable logic blocks, or other modules within a SoC and/or a multichip package.

Accordingly, the various components described herein may be implemented using an integrated circuit fabricated on a single chip, across multiple chips within a same chip package, or across chips in different chip packages.

The system includes a signal bus 102 that is configured to route signals between various circuit blocks, programmable logic blocks, or other components of the system 100, including at least one semiconductor device 112, such as an application-specific integrated circuit (ASIC). Various other components may be coupled to one or more data ports of the signal bus 102, such as a microcontroller 104, a memory 106, and/or a network I/O circuit 108. Other circuits 114 or other signal buses may be coupled to the signal bus 102 via a bus connection 110 or another suitable interface. In this manner, the semiconductor device 112 can be accessed by one or more other components of the system 100 via the signal bus 102. Likewise, the semiconductor device 112 can access one or more other components of the system 100 via the signal bus 102.

As will be described in further detail below, the semiconductor device 112 can be any semiconductor or other SoC device that is designed to mitigate against, for example, reverse engineering, circuit modification, and IP theft of semiconductor devices, or otherwise incorporates other secure attributes, techniques, or features, such as described herein.

Other componentry and functionality not reflected in FIG. 1 will be apparent in light of this disclosure, and it will be appreciated that other embodiments are not limited to any particular hardware configuration. For example, the microcontroller 104 can be any suitable processor and may include one or more coprocessors or controllers. In some examples, the processor 104 can be implemented as any number of processor cores. The processor 104 (or processor cores) can be any type of processor, such as, for example, a micro-processor, an embedded processor, a digital signal processor (DSP), a graphics processor (GPU), a network processor, a field programmable gate array or other device configured to execute code. The processor 104 can include multithreaded cores in that they may include more than one hardware thread context (or “logical processor”) per core. The processor 104 can be implemented as a complex instruction set computer (CISC) or a reduced instruction set computer (RISC) processor. In some examples, the processor 104 can include, for example, a micro-processor, an embedded processor, a digital signal processor (DSP), a graphics processor (GPU), a network processor, a field programmable gate array (FPGA), application-specific integrated circuit (ASIC) or other device configured to execute code. The processor 104 can be configured to execute an operating system (OS), such as Google Android (by Google Inc. of Mountain View, Calif.), Microsoft Windows (by Microsoft Corp. of Redmond, Wash.), Apple OS X (by Apple Inc. of Cupertino, Calif.), Linux, or a real-time operating system (RTOS). As will be appreciated in light of this disclosure, the techniques provided herein can be implemented without regard to the particular operating system provided in conjunction with the system 100, and therefore may also be implemented using any suitable existing systems or platforms.

The memory 106 can be implemented using any suitable type of digital storage including, for example, flash memory and/or random-access memory (RAM). In some examples, the memory 106 includes various layers of standard memory hierarchy and/or standard memory caches. The memory 106 can be implemented as a volatile memory device such as, but not limited to, a RAM, dynamic RAM (DRAM), or static RAM (SRAM) device.

The network I/O 108 represents any suitable type of wired and/or wireless network interface designed to receive and transmit signals across a network. Wired communication may conform to existing standards, such as, for example, Ethernet. Wireless communication may conform to existing standards, such as, for example, cellular communications including LTE (Long Term Evolution), Wireless Fidelity (Wi-Fi), Bluetooth, and/or Near Field Communication (NFC). Examples of such wireless networks include, but are not limited to, wireless local area networks, wireless personal area networks, wireless metropolitan area networks, cellular networks, and satellite networks.

According to at least some examples, the processor 104, the memory 106, the network I/O 108, the semiconductor device 112, and any other devices coupled to the signal bus 102 may be designated as being unsecure sources. An unsecure source or device may be any circuit or device that has the possibility of being compromised in some way (e.g., unauthorized use or examination), and thus cannot be fully trusted.

It will be appreciated that in some examples, some of the various components of the system 100 can be combined or integrated in a SoC architecture. In some examples, the components may be hardware components, firmware components, software components or any suitable combination of hardware, firmware, or software.

Unless specifically stated otherwise, it may be appreciated that terms such as “processing,” “computing,” “calculating,” “determining,” or the like refer to the action and/or process of a computer or computing system, or similar electronic computing device, that manipulates and/or transforms data represented as physical quantities (for example, electronic) within the registers and/or memory units of the computer system into other data similarly represented as physical entities within the registers, memory units, or other such information storage transmission or displays of the computer system. The embodiments are not limited in this context.

### Redacted Logic Device

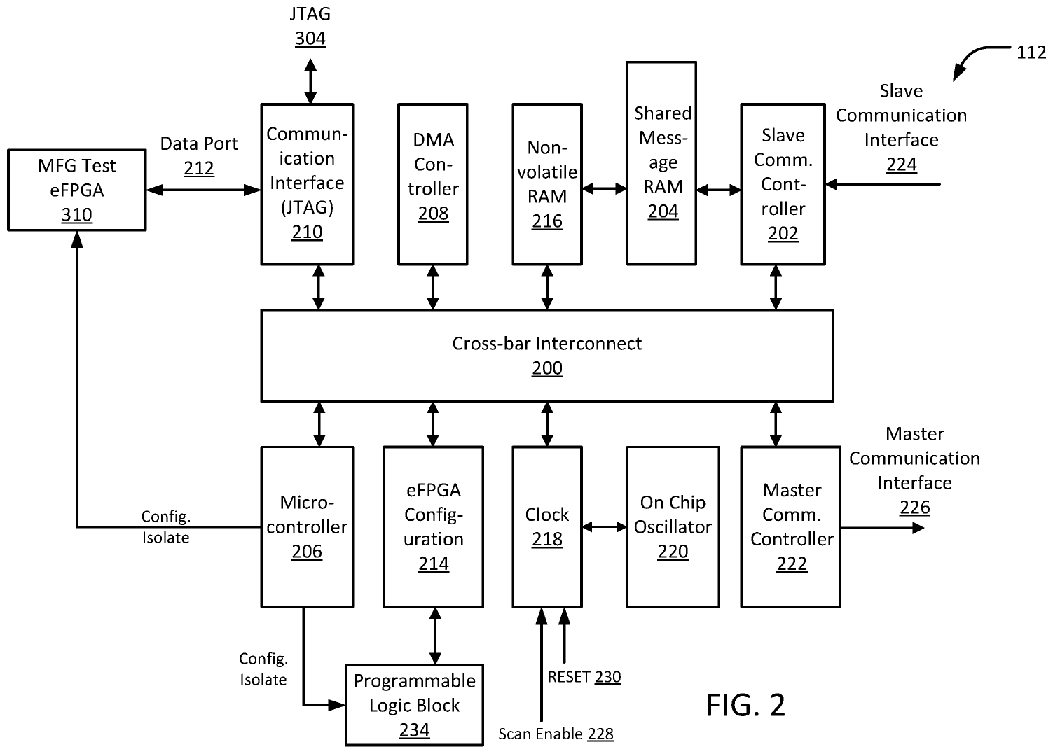

FIG. 2 is a block diagram of the semiconductor device 112 of FIG. 1, in accordance with an example of the present disclosure. The semiconductor device 112 can be implemented, for example, as an FPGA or ASIC system. The semiconductor device 112 includes a cross-bar interconnect 200, a slave communication controller 202, a shared message random access memory (RAM) 204, a microcontroller 206, a direct memory access (DMA) controller 208, a communications interface 210, a data port 212, an electronic FPGA (eFPGA) configuration module 214, a non-volatile RAM (NVRAM) 216, a clock 218, an on-chip oscillator 220, and a slave communication controller 202. The device 112 can include one or more programmable logic blocks 234, or test cells, which can be used in conjunction with testing, debugging, or boundary scan operations to test or otherwise exercise the operation of the device 112. Each of the programmable logic blocks 234 is accessible via the cross-bar interconnect 200.

The slave communication controller 202 is operatively coupled to a slave communication interface 224, the cross-bar interconnect 200, and the shared message RAM 204. The microcontroller 206 is operatively coupled to the cross-bar interconnect 200 and the shared message RAM 204. The DMA controller 208 is operatively coupled to the cross-bar interconnect 200. The communication interface 210 is operatively coupled to the cross-bar interconnect 200 and the data port 212. In some examples, the communication interface 210 includes a JTAG interface. The eFPGA configuration module 214 is operatively coupled to the cross-bar interconnect 200. The NVRAM 216 is operatively coupled to the cross-bar interconnect 200. The clock 218 is operatively coupled to the cross-bar interconnect 200 and the on-chip oscillator 220. The clock 218 is configured to receive a scan enable signal 228 and a RESET signal 230. The master communication controller 222 is operatively coupled to the cross-bar interconnect 200 and a master communication interface 226. In some examples, the semiconductor device 112 includes a manufacturing test eFPGA 310, although it will be understood that the manufacturing test eFPGA 310 can be an external component, or part of an external component (such as an ASIC) that is communicatively and/or operatively coupled to the semiconductor device 112.

The cross-bar interconnect 200 is configured to provide data and signal communications between various components of the device 112, such as communications between the microcontroller 206, the communication interface 210 via the data port 212, the eFPGA configuration module 214, the NVRAM 216, and the clock 218. In this manner, the cross-bar interconnect 200 can provide access to various components of the device 112 form the data port 212 via the communication interface 210. For example, a user can use the data port 212 to read data from, or write data to, the NVRAM 216; to access debug functionality of the device 112; to modify a FPGA configuration in the eFPGA configuration module 214; and to modify the clock 218. However, as noted above, when the device 112 is under the control of an untrusted foundry or other entity, a user can potentially obtain information about the logic design of the device 112 via the data port 212 (e.g., using a boundary scan function) or to otherwise alter the functionality of the device (e.g., by re-clocking the device 112, which can cause the device 112 to enter an unprotected state). To this end, the device 112 includes various design aspects and elements that can be used to prevent unauthorized use or examination, such as described below. In particular, the FPGA logic of the manufacturing test eFPGA 310 is redacted; that is, the manufacturing test eFPGA 310 contains no operable FPGA load file or other executable code until the semiconductor device 112 is shipped from the untrusted foundry to a trusted facility for testing. Once at the trusted facility, the manufacturing test eFPGA 310 is loaded with an operable FPGA load file.

### Redacted Programmable Logic Block

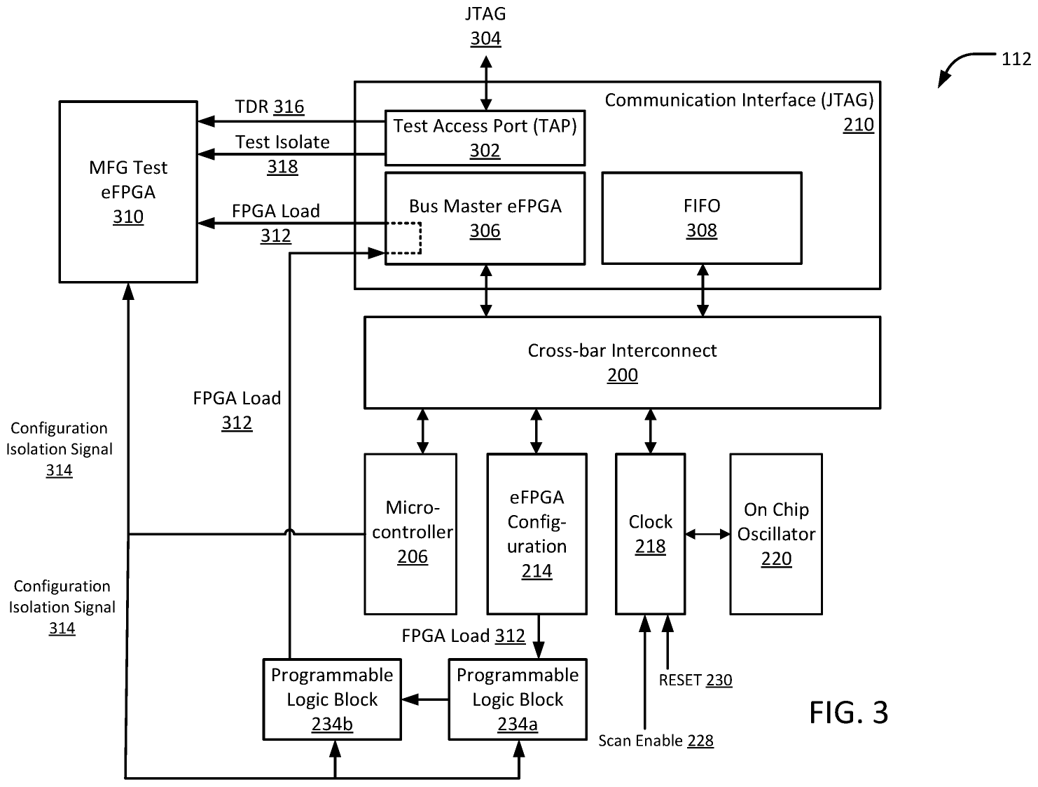

FIG. 3 is a block diagram of a portion of the semiconductor device 112 of FIGS. 1 and 2, in accordance with an example of the present disclosure. The communication interface 210, in some examples, is a JTAG interface with a test access port 302 communicatively coupled to a JTAG data port 304. The communication interface 210 further includes at least one programmable logic block, such as a bus master eFPGA 306 and the manufacturing test eFPGA 310, and a first-in-first out (FIFO) buffer 308. In some examples, in addition to the bus master eFPGA 306 and the manufacturing test eFPGA 310, the semiconductor device 112 includes multiple programmable logic blocks 234a, 234b, etc. The manufacturing test eFPGA 310 is communicatively coupled to the bus master eFPGA 306. In such examples, each of the programmable logic blocks (e.g., 234a, 234b, etc.) the bus master eFPGA 306, and the manufacturing test eFPGA 310 are communicatively coupled in series to the eFPGA configuration module 214 for loading data (e.g., an FPGA load file such as indicated in FIG. 3 as FPGA load 312) and further configuration and/or control. The manufacturing test eFPGA 310 is the last programmable logic block on the serial communication chain (FPGA load 312 starting at the eFPGA configuration module 214 and ending at the manufacturing test eFPGA 310), such as shown in FIG. 3.

The programmable logic blocks 234a, 234b, and the manufacturing test eFPGA 310 are each configured to operate in a boundary scan mode (also referred to as a scan mode). The FIFO 308 is configured to store FPGA configuration data and load files that can be transferred into the programmable logic blocks 234a, 234b, and the manufacturing test eFPGA 310 via the eFPGA configuration module 214. Furthermore, the communication interface 210 (e.g., JTAG) is a slave for the FIFO 308 and the microcontroller 206 controls data traffic via the FIFO 308. This is important because it means the communication interface 210 (e.g., JTAG) during load cycle has no control on the how much data passes through the FIFO 308. In other words, the microcontroller 206 pulls the data instead of the communication interface 210 pushing the data. For example, such as described in further detail below, the eFPGA configuration module 214, in a first modality, retrieves data from the FIFO buffer 308 and transfers the data to the programmable logic blocks 234a, 234b, and the manufacturing test eFPGA 310. The clock 218 is configured to enable the scan mode of the programmable logic blocks 234a, 234b, and the manufacturing test eFPGA 310, and/or to de-assert a reset signal to the same components. The clock 218 is further configured to disable the scan mode of the programmable logic blocks 234a, 234b, and the manufacturing test eFPGA 310 and/or to assert the reset signal to the same components. In some examples, the clock 218 is controlled by the on-chip oscillator 220, which is configured to internally generate a clock signal for operation of the semiconductor device 112.

Initially, the manufacturing test eFPGA 310 is redacted; that is, the manufacturing test eFPGA 310 contains no operable FPGA load file or other executable code. In some examples, the programmable logic blocks 234a, 234b, and/or the bus master eFPGA 306 can be redacted; however, it is not necessary to redact all such programmable logic blocks. By redacting the manufacturing test eFPGA 310, it is not possible to access the programmable logic blocks 234a, 234b, from the JTAG data port 304 via the manufacturing test eFPGA 310.

Next, in a first modality after power is applied to the semiconductor device 112, the microcontroller 206 loads the manufacturing test eFPGA 310 with executable code (e.g., an FPGA load file). The microcontroller 206 causes the eFPGA configuration module 214 to load the executable code, or other data, into the manufacturing test eFPGA 310 from the FIFO buffer 308 of the communication interface 210. The FIFO buffer 308 receives the executable code or other data from the JTAG data port 304. The boot code of the microcontroller 206 is hardcoded such that its operation cannot be reconfigured or otherwise altered. In the first modality, during the FPGA load, the output data ports of all programmable logic blocks, including the data port 212 or other functional input/output of the manufacturing test eFPGA 310, are inactive (e.g., the functional outputs are in a steady state, such as logical 0 or 1), and only the JTAG data port 304 is active. In this manner, all other functional I/O are inactive so that other functional paths in the programmable logic blocks cannot be utilized as attack vectors without the FPGA load completed. The microcontroller 206 asserts a configuration isolation signal 314 to the manufacturing test eFPGA 310. The data port 212 of the manufacturing test eFPGA 310, and the data ports of all other programmable logic blocks 234a, 234b, etc., are configured to be communicatively isolated from the programmable logic block while the configuration isolation signal is asserted. This prevents accessing, for example, the output of the manufacturing test eFPGA 310, thereby protecting the semiconductor device 112 from unauthorized access or reverse engineering during the FPGA load. Furthermore, in the first modality, the programmable logic blocks 234a, 234b are held in reset and all clock signals are gated off to inhibit operation such that only an FPGA load can be performed in the first modality.

A second modality of the semiconductor device 112 occurs subsequent to loading the data into the programmable logic blocks 234a, 234b, and the manufacturing test eFPGA 310.

In the second modality, the microcontroller 206 de-asserts the configuration isolation signal 314 from the manufacturing test eFPGA 310. The output data port of the manufacturing test eFPGA 310, and the output data ports of all other programmable logic blocks 234a, 234b, and the manufacturing test eFPGA 310 are configured to be communicatively coupled to the programmable logic block 234a, 234b, and the manufacturing test eFPGA 310 (e.g., operating normally) while the configuration isolation signal is de-asserted.

In the second modality, the programmable logic blocks 234a, 234b, and the manufacturing test eFPGA 310 are enabled to provide a full access scan and to operate in one of several manufacturing test modes, including a test mode, a scan enable mode, a scan clock mode, a quiescent power-supply current (IDDQ) mode, a burn in mode, and a reset disable mode. For example, the communication interface 210 is configured to send a test data register (TDR) signal 316 to the manufacturing test eFPGA 310, which causes the manufacturing test eFPGA 310 to enter a test mode based on a value in the TDR signal received via the JTAG data port 304. The communication interface 210 is further configured to send a test isolate signal 318 to the manufacturing test eFPGA 310, which causes the manufacturing test eFPGA 310 be locked down in a test mode, restricting the manufacturing test eFPGA 310 to executing automated test pattern generation (ATPG) patterns (for example, preventing the manufacturing test eFPGA 310 from being testable itself by rejecting scans coming other than from the TAP 302). The second modality is intended to be used in a trusted facility (e.g., a facility other than the manufacturing foundry).

After manufacturing tests are completed and the semiconductor device 112 is in the field, the manufacturing test eFPGA 310 can be loaded with a field FPGA load that causes the manufacturing test eFPGA 310 to operate in a functional mode only. In the functional mode, the manufacturing test modes of the manufacturing test eFPGA 310 (e.g., the TDR signals) are disabled for field use.

### Boundary Scan and Clock Control

In accordance with an example of the present disclosure, the manufacturing test eFPGA 310 is configured to operate in a manufacturing test mode while the TAP 302 asserts the test isolate signal 318. The clock 218 is configured to enable the manufacturing test mode of the manufacturing test eFPGA 310 and/or to de-assert a reset signal to the manufacturing test eFPGA 310 while in the second modality. In some examples, the clock 218 is controlled by the on-chip oscillator 220, which is configured to internally generate a clock signal for operation of the device 112.

In some examples, the device 112 is configured such that when the manufacturing test eFPGA 310 has no loaded configuration, or is loaded with an improper configuration, the boundary scan function is disabled and/or the RESET signal 230 is held in a constant state to prevent reset and operation of the semiconductor device 112 (e.g., the clock 218 is disabled).

In some examples, the slave communication controller 202 is configured to receive a data access command via the slave communication interface 224. For example, the command can include a request to access data stored in the NVRAM 216. In such examples, the command is passed to the microcontroller 206 via the shared message RAM 204. The microcontroller 206 retrieves the command from the shared message RAM 204. The microcontroller 206 is configured to determine whether the command is valid (e.g., has access rights to the NVRAM 216), and if valid, to send the data stored in the NVRAM 216 to the master communication controller 222 for output via the master communication interface 226.

### External Command Control

In accordance with an example of the present disclosure, the microcontroller 206 is configured to receive one or more commands from the shared message RAM 204. The commands can include, for example, a request to output data from any portion of the semiconductor device 112 to the master communication interface 226 via the master communication controller 222. The commands can be loaded from the slave communication interface 224 into the shared message RAM 204 via the slave communication controller 202. The microcontroller 206 is further configured to determine whether the one or more commands are authorized to be executed. If the microcontroller 206 determines that the one or more commands are authorized, the results of the commands (e.g., data) are output to the master communication interface 226 via the master communication controller 222. Otherwise, the commands are not executed.

### Semiconductor Device Modalities

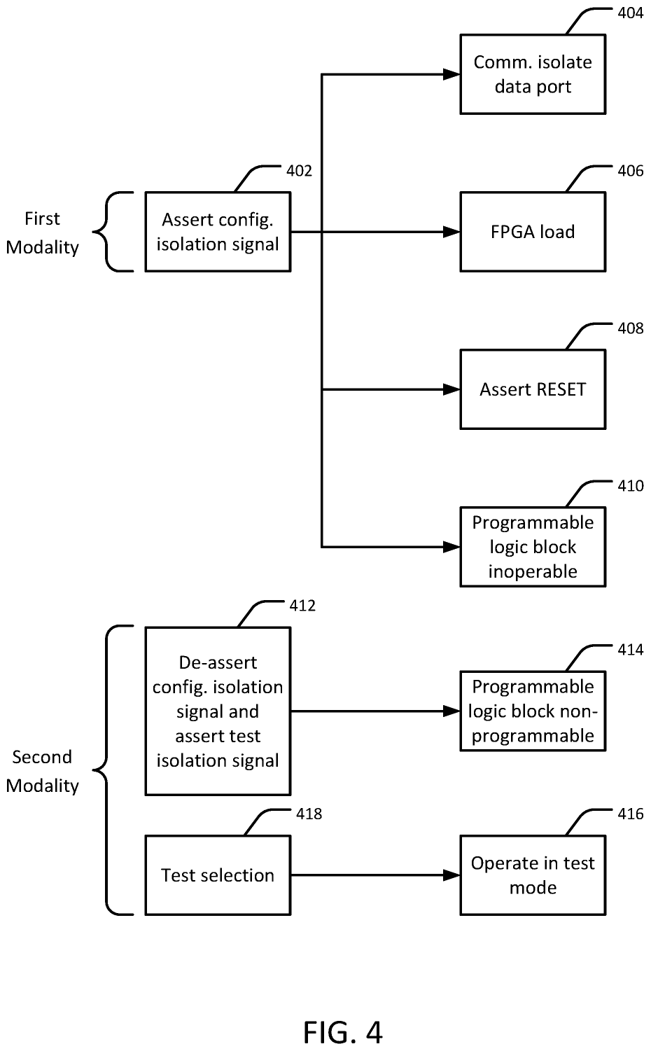

FIG. 4 is a block diagram representing first and second modalities of the semiconductor device 112 of FIGS. 1, 2 and 3, in accordance with an example of the present disclosure. In a first modality, the microcontroller 206 asserts 402 the configuration isolation signal 314 to the data port(s) of the programmable logic blocks 234a, 234b, and/or the manufacturing test eFPGA 310. The configuration isolation signal, while asserted, causes the data port(s) to be communicatively isolated 404 from the respective programmable logic blocks. Further, in the first modality, the microcontroller 206 causes 406 data, such as an FPGA load, to be loaded into the programmable logic blocks 234a, 234b, and/or the manufacturing test eFPGA 310 from the FIFO buffer 308 of the communication interface 210. For example, the eFPGA configuration module 214 can be configured to load the data into the programmable logic blocks 234a, 234b, and/or the manufacturing test eFPGA 310 from the FIFO buffer 308 while in the first modality. Further, in the first modality, the clock 218 is configured to assert 408 a RESET signal, thereby disabling operation of the programmable logic blocks 234a, 234b, and/or the manufacturing test eFPGA 310 or otherwise rendering one or more of them inoperable 410. In some examples, the clock 218 is configured to ignore or bypass the scan enable signal 228 to prevent scan strings from being executed (disable boundary scan).

In a second modality, which occurs subsequent to loading the data into the programmable logic blocks 234a, 234b, and/or the manufacturing test eFPGA 310, the microcontroller 206 de-asserts 412 the configuration isolation signal 314 from the data port(s) of the programmable logic blocks 234a, 234b, and/or the manufacturing test eFPGA 310. Further, in the second modality, the programmable logic blocks 234a, 234b, and/or the manufacturing test eFPGA 310 is configured to be in a non-programmable state 414 responsive to receiving the test isolate signal 318 in the second modality. The test isolate signal 318 causes a configuration signal, such as the FPGA load 312 from the eFPGA 310, to be isolated from the programmable logic blocks 234a, 234b, and/or the manufacturing test eFPGA 310, to inhibit the FPGA load.

Further, in the second modality, the manufacturing test eFPGA 310 is further configured to operate 416 in a test mode responsive to a presence of a test selection signal 418, such as the TDR signal 316.

In a third modality, which occurs subsequent to operating in the test mode, the test mode of the manufacturing test eFPGA 310 is disabled for field use, which allows the manufacturing test eFPGA 310 to operate in a functional mode for any test selection (e.g., TDR) signal.

### Process Flow

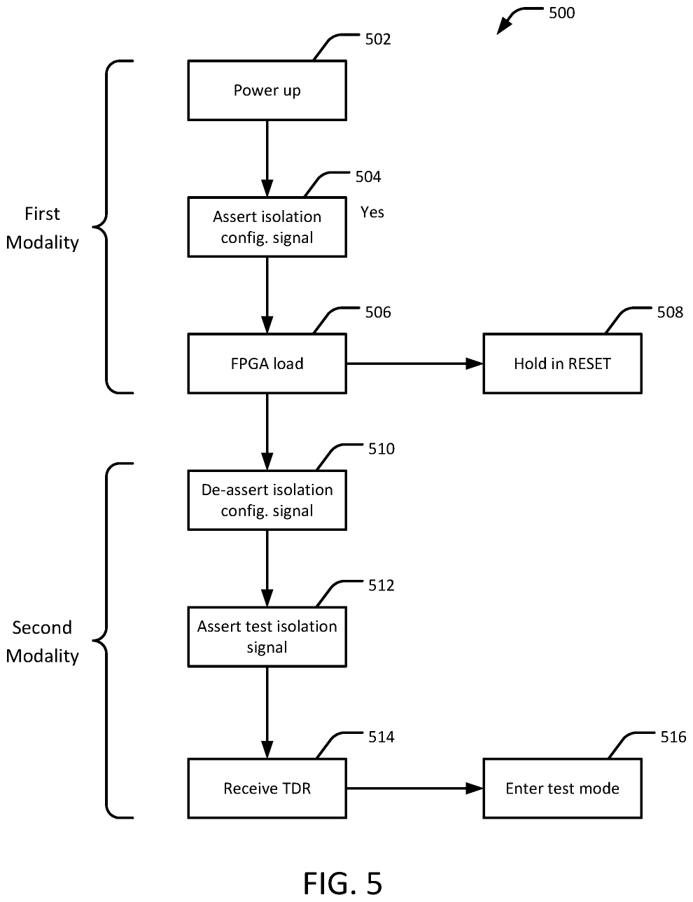

FIG. 5 is a flow diagram of an example process 500 for operating the semiconductor device 112 of FIGS. 1, 2, and 3, in accordance with an example of the present disclosure. The process 500 includes applying power 502 to the semiconductor device, which places the device in a first modality. The process 500 further includes asserting 504 a configuration isolation signal to one or more programmable logic blocks of the device while in the first modality, which causes the data port(s) to be communicatively isolated 404 from the respective programmable logic blocks.

The process 500 further includes loading 506 the one or more programmable logic blocks while in the first modality. The programmable logic block(s) can be loaded via a communication interface (e.g., a JTAG interface) and internal system bus (e.g., a cross-bar interconnect) of the device while the programmable logic block(s) are communicatively isolated from their respective data ports, including the output data ports. In some examples, the process 500 includes holding 508 the one or more programmable logic blocks in reset to inhibit operation.

After the one or more programmable logic blocks are loaded, the process 500 further includes de-asserting 510 the isolation configuration signal while in a second modality. The one or more programmable logic blocks are each configured to be in a non-programmable state responsive to receiving the test isolation signal in the second modality.

The process 500 further includes asserting 512 a test isolation signal and receiving 514 a TDR signal from the communication interface of the device. For example, the communication interface is configured to send the TDR signal to the programmable logic block (e.g., the manufacturing test eFPGA 310), which causes the programmable logic block to enter 516 a test mode based on a value in the TDR signal received via the communication interface. The communication interface is further configured to send the test isolate signal to the programmable logic block, which causes the programmable logic block to be locked down in a test mode, restricting the programmable logic block to executing an ATPG pattern. As noted above, the second modality is intended to be used in a trusted facility (e.g., a facility other than the manufacturing foundry.

### Further Example Embodiments

The following examples pertain to further embodiments, from which numerous permutations and configurations will be apparent.

Example 1 provides a semiconductor device comprising a data port; a programmable logic block for executing a manufacturer test; and a processor operatively coupled to the data port, the processor configured to assert, in a first modality, a configuration isolation signal to the data port, the data port configured to be communicatively isolated from the programmable logic block while the configuration isolation signal is asserted, and de-assert, in a second modality, the configuration isolation signal from the data port, the data port further configured to be communicatively coupled to the programmable logic block while the configuration isolation signal is de-asserted.

Example 2 includes the subject matter of Example 1, further comprising a communication interface communicatively coupled to the programmable logic block, wherein the processor is further configured to cause, in the first modality, data to be loaded into the programmable logic block from a first-in-first-out (FIFO) buffer of the communication interface, and wherein the second modality occurs subsequent to loading the data into the programmable logic block.

Example 3 includes the subject matter of Example 2, further comprising an electronic field-programmable gate array (eFPGA) configuration module configured to load the data into the programmable logic block from the FIFO buffer while in the first modality.

Example 4 includes the subject matter of any one of Examples 2 and 3, wherein the data port is a first data port, the programmable logic block is a first programmable logic block, the data is first data, and wherein the processor is further configured to: assert, in a first modality, the configuration isolation signal to a second data port, the second data port configured to be communicatively isolated from a second programmable logic block while the configuration isolation signal is asserted; cause, in the first modality, second data to be loaded into the second programmable logic block from the FIFO buffer of the communication interface; and de-assert, in a second modality, the configuration isolation signal from the second data port, the second data port further configured to be communicatively coupled to the second programmable logic block while the configuration isolation signal is de-asserted.

Example 5 includes the subject matter of any one of Examples 2-4, wherein the communication interface includes a JTAG interface.

Example 6 includes the subject matter of anyone of Examples 1-5, further comprising a clock configured to assert, in the first modality, a RESET signal, thereby disabling operation of the programmable logic block.

Example 7 includes the subject matter of any one of Examples 1-6, wherein the processor includes hardcoded boot code.

Example 8 includes the subject matter of any one of Examples 1-7, wherein the programmable logic block is configured to be in a non-programmable state responsive to receiving a test isolation signal in the second modality.

Example 9 includes the subject matter of Example 8, wherein the test isolation signal causes a configuration signal to be isolated from the programmable logic block.

Example 10 includes the subject matter of any one of Examples 8 and 9, wherein the programmable logic block is further configured to operate in a test mode responsive to a presence of a test selection signal in the second modality, and further configured to operate in a non-test mode responsive to an absence of the test selection signal.

Example 11 provides an application specific integrated circuit (ASIC) system comprising a data port; a programmable logic block for executing a manufacturer test; a processor communicatively coupled to the programmable logic block; a communication interface communicatively coupled to the processor and to the data port; an electronic field-programmable gate array (eFPGA) configuration module configured to load data into the programmable logic block from a first-in-first-out (FIFO) of the communication interface; and a clock operatively coupled to the programmable logic block, wherein in a first modality, the data port and the clock are each isolated from the programmable logic block, boundary scan operations are disabled, a RESET signal is held in a constant state, and/or redacted code of the programmable logic block is rendered inoperable, and wherein in a second modality, the data port and the clock are each communicatively coupled to the programmable logic block, the boundary scan operations are enabled, the RESET signal is not held in the constant state, and/or the redacted code is operable.

Example 12 includes the subject matter of Example 11, wherein the communication interface includes a JTAG interface.

Example 13 includes the subject matter of any one of Examples 11 and 12, wherein in the first modality, the processor is configured to cause data to be loaded into the programmable logic block from the FIFO.

Example 14 includes the subject matter of any one of Examples 11-13, wherein the processor includes hardcoded boot code.

Example 15 includes the subject matter of any one of Examples 11-14, wherein the programmable logic block is configured to be in a non-programmable state responsive to receiving a test isolation signal in the second modality.

Example 16 includes the subject matter of any one of Examples 11-15, wherein the test isolation signal causes a configuration signal to be isolated from the programmable logic block.

Example 17 includes the subject matter of Example 16, wherein the programmable logic block is further configured to operate in a test mode responsive to a presence of a test selection signal in the second modality, and further configured to operate in a non-test mode responsive to an absence of the test selection signal.

Example 18 includes the subject matter of any one of Examples 11-17, wherein in the first modality, the clock is configured to assert a RESET signal.

Example 19 includes the subject matter of any one of Examples 11-18, wherein in the second modality, the clock is configured to disable the boundary scan mode of the programmable logic block.

Example 20 provides a method of operating a semiconductor device having a data port and a programmable logic block, the method comprising communicatively isolating the data port from the programmable logic, responsive to a configuration isolation signal being asserted to the data port; loading the programmable logic block with a load file; communicatively coupling the data port to the programmable logic block, responsive to the configuration isolation signal being de-asserted from the data port; and asserting a test isolation signal to the programmable logic block, causing the programmable logic block to be in a non-programmable state responsive to a test isolation signal being asserted to the programmable logic block.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A semiconductor device, comprising:
a data port;
a programmable logic block for executing a manufacturer test; and
a processor operatively coupled to the data port, the processor configured to
assert, in a first modality, a configuration isolation signal to the data port, the data port configured to be communicatively isolated from the programmable logic block while the configuration isolation signal is asserted, and
de-assert, in a second modality, the configuration isolation signal from the data port, the data port further configured to be communicatively coupled to the programmable logic block while the configuration isolation signal is de-asserted.

2. The semiconductor device of claim 1, further comprising a communication interface communicatively coupled to the programmable logic block, wherein the processor is further configured to cause, in the first modality, data to be loaded into the programmable logic block from a first-in-first-out (FIFO) buffer of the communication interface, and wherein the second modality occurs subsequent to loading the data into the programmable logic block.

3. The semiconductor device of claim 2, further comprising an electronic field-programmable gate array (eFPGA) configuration module configured to load the data into the programmable logic block from the FIFO buffer while in the first modality.

4. The semiconductor device of claim 2, wherein the data port is a first data port, the programmable logic block is a first programmable logic block, the data is first data, and wherein the processor is further configured to:
assert, in a first modality, the configuration isolation signal to a second data port, the second data port configured to be communicatively isolated from a second programmable logic block while the configuration isolation signal is asserted;
cause, in the first modality, second data to be loaded into the second programmable logic block from the FIFO buffer of the communication interface; and
de-assert, in a second modality, the configuration isolation signal from the second data port, the second data port further configured to be communicatively coupled to the second programmable logic block while the configuration isolation signal is de-asserted.

5. The semiconductor device of claim 2, wherein the communication interface includes a JTAG interface.

6. The semiconductor device of claim 1, further comprising a clock configured to assert, in the first modality, a RESET signal, thereby disabling operation of the programmable logic block.

7. The semiconductor device of claim 1, wherein the processor includes hardcoded boot code.

8. The semiconductor device of claim 1, wherein the programmable logic block is configured to be in a non-programmable state responsive to receiving a test isolation signal in the second modality.

9. The semiconductor device of claim 8, wherein the test isolation signal causes a configuration signal to be isolated from the programmable logic block.

10. The semiconductor device of claim 8, wherein the programmable logic block is further configured to operate in a test mode responsive to a presence of a test selection signal in the second modality, and further configured to operate in a non-test mode responsive to an absence of the test selection signal.

11. An application specific integrated circuit (ASIC) system, comprising:
a data port;
a programmable logic block for executing a manufacturer test;
a processor communicatively coupled to the programmable logic block;
a communication interface communicatively coupled to the processor and to the data port;
an electronic field-programmable gate array (eFPGA) configuration module configured to load data into the programmable logic block from a first-in-first-out (FIFO) of the communication interface; and
a clock operatively coupled to the programmable logic block,
wherein in a first modality, the data port and the clock are each isolated from the programmable logic block, boundary scan operations are disabled, a RESET signal is held in a constant state, and/or redacted code of the programmable logic block is rendered inoperable, and
wherein in a second modality, the data port and the clock are each communicatively coupled to the programmable logic block, the boundary scan operations are enabled, the RESET signal is not held in the constant state, and/or the redacted code is operable.

12. The ASIC system of claim 11, wherein the communication interface includes a JTAG interface.

13. The ASIC system of claim 11, wherein in the first modality, the processor is configured to cause data to be loaded into the programmable logic block from the FIFO.

14. The ASIC system of claim 11, wherein the processor includes hardcoded boot code.

15. The ASIC system of claim 11, wherein the programmable logic block is configured to be in a non-programmable state responsive to receiving a test isolation signal in the second modality.

16. The ASIC system of claim 15, wherein the test isolation signal causes a configuration signal to be isolated from the programmable logic block.

17. The ASIC system of claim 16, wherein the programmable logic block is further configured to operate in a test mode responsive to a presence of a test selection signal in the second modality, and further configured to operate in a non-test mode responsive to an absence of the test selection signal.

18. The ASIC system of claim 11, wherein in the first modality, the clock is configured to assert a RESET signal.

19. The ASIC system of claim 11, wherein in the second modality, the clock is configured to disable the boundary scan mode of the programmable logic block.

20. A method of operating a semiconductor device having a data port and a programmable logic block, the method comprising:
communicatively isolating the data port from the programmable logic, responsive to a configuration isolation signal being asserted to the data port;
loading the programmable logic block with a load file;
communicatively coupling the data port to the programmable logic block, responsive to the configuration isolation signal being de-asserted from the data port; and
asserting a test isolation signal to the programmable logic block, causing the programmable logic block to be in a non-programmable state responsive to a test isolation signal being asserted to the programmable logic block.
